(19) United States
(12) Patent Application Publication
(10) Pub. No.: US 2026/0181822 A1
(43) Pub. Date: Jun. 25, 2026

(54) RADIATOR AND TERMINAL DEVICE

(71) Applicants: CHAMP TECH OPTICAL (FOSHAN) CORPORATION, Foshan (CN); Foxconn Technology Co., Ltd., New Taipei (TW)

(72) Inventors: MENG FU, Foshan (CN); JIN-RONG XIE, Foshan (CN); FU-SHENG LUO, Foshan (CN)

(21) Appl. No.: 19/091,468

(22) Filed: Mar. 26, 2025

(30) Foreign Application Priority Data
Dec. 20, 2024 (CN) 202411902556.X

(51) Int. Cl. H05K 7/20

(52) U.S. Cl. CPC H05K 7/20263; H05K 7/20272

(57) ABSTRACT

A radiator includes an inlet connector, an outlet connector, and at least one heat dissipating assembly. The heat dissipating assembly includes heat dissipating plates and a liquid separator. The heat dissipating plate includes a first channel and a second channel. The liquid separator includes a liquid inlet, a liquid outlet, a plurality of outlets, and a plurality of inlets. The liquid inlet communicates with the inlet connector, the liquid outlet communicates with the outlet connector, the liquid inlet communicates with the plurality of outlets, the liquid outlet communicates with the plurality of inlets, the plurality of outlets communicates with the first channel, and the plurality of inlets communicates with the second channel. The present disclosure further provides a terminal device.

### FIELD

The subject matter herein generally relates to heat dissipation, and more particularly, to a radiator and a terminal device.

### BACKGROUND

A terminal device, such as a server, may include a number of memory modules and a radiator for dissipating heat from the memory modules. The heat dissipation efficiency of the radiator may be low. Therefore, there is a room for improvement in the art.

### BRIEF DESCRIPTION OF THE DRAWINGS

Implementations of the present technology will now be described, by way of example only, with reference to the attached figures.

FIG. 1 is a diagrammatic view illustrating a terminal device according to an embodiment of the present disclosure.

FIG. 2 is a diagrammatic view illustrating a radiator of the terminal device shown in FIG. 1.

FIG. 3 is a cross-sectional view of the radiator along a view line A-A of FIG. 2.

FIG. 4 is an exploded view of the radiator shown in FIG. 2.

FIG. 5 is similar to FIG. 4, but showing the radiator viewed from another angle

FIG. 6 is a cross-sectional view of the radiator along a view line B-B of FIG. 2.

FIG. 7 is a cross-sectional view of the radiator along a view line C-C of FIG. 4.

FIG. 8 is a diagrammatic view illustrating a radiator according to another embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

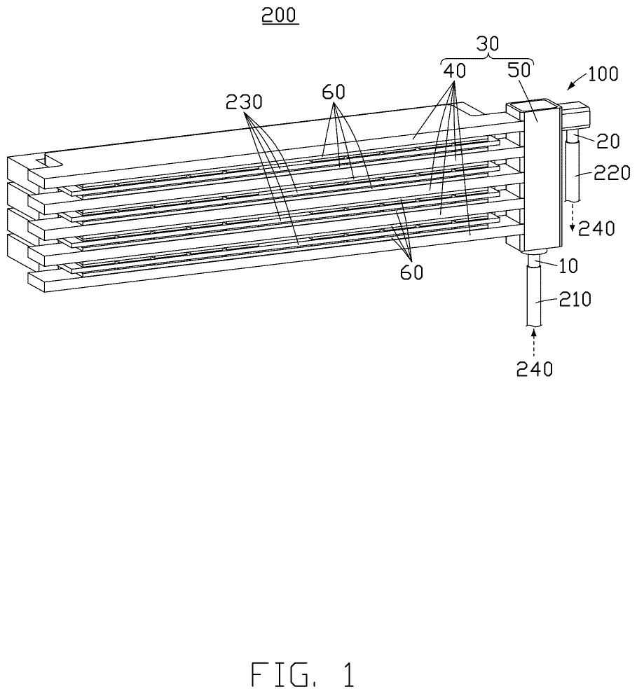

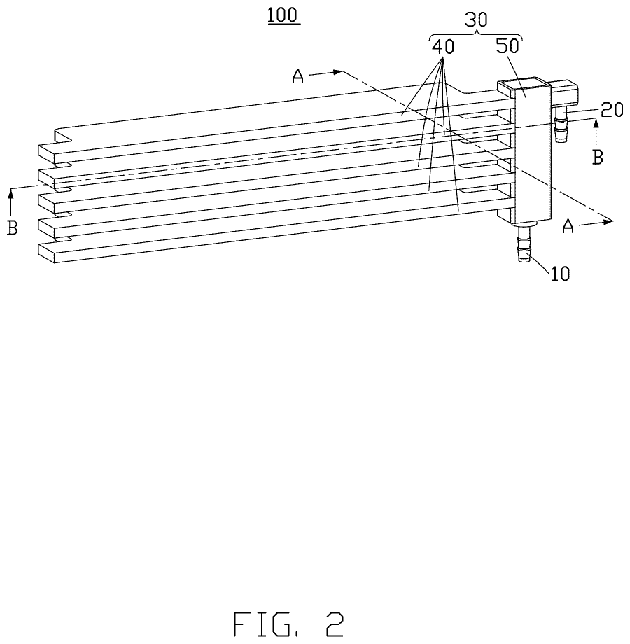

FIG. 1 is a diagrammatic view illustrating a terminal device 200 according to an embodiment of the present disclosure. FIG. 2 is a diagrammatic view illustrating a radiator 100 shown in FIG. 1. The terminal device 200 includes the radiator 100, an inlet tube 210, an outlet tube 220, and at least one working member 230. The working member 230 is connected to the radiator 100, and the inlet tube 210 and the outlet tube 220 communicate with the radiator 100.

The working member 230 generates heat during operation. A working fluid 240 is injected into the radiator 100 through the inlet tube 210, that is, the working fluid 240 enters the radiator 100 from the inlet tube 210. The working fluid 240 further flows through the radiator 100 and expels from the outlet tube 220. As the working fluid 240 flows, the working fluid 240 dissipates the heat generated by the working member 230, thereby maintaining the working environment of the working member 230 in a suitable temperature range.

The terminal device 200 can be a server. The working member 230 can be a memory module, chip, etc. The working fluid 240 can be water.

The radiator 100 can include an inlet connector 10, an outlet connector 20, and at least one heat dissipating assembly 30. In the embodiment, the radiator 100 includes one heat dissipating assembly 30. The inlet connector 10 communicates with the inlet tube 210, the outlet connector 20 communicates with the outlet tube 220, and the heat dissipating assembly 30 communicates with both the inlet tube 210 and the outlet tube 220. The working fluid 240 enters the inlet tube 210 and flows through the inlet connector 10, the heat dissipating assembly 30, and the outlet connector 20, and finally expels from the outlet tube 220.

The heat dissipating assembly 30 includes a plurality of heat dissipating plates 40 and a liquid separator 50 connected to the heat dissipating plates 40. Two adjacent heat dissipating plates 40 are spaced from each other, and the working member 230 can be located between two adjacent heat dissipating plates 40. Two surfaces of the working member 230 can be in direct contact with two adjacent heat dissipating plates 40, or the surfaces of the working member 230 can be in indirect contact with the heat dissipating plates 40.

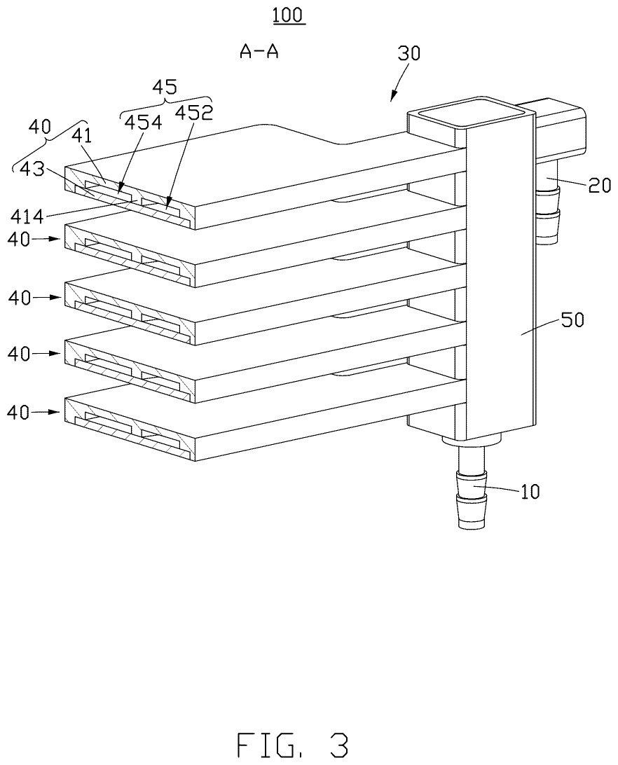

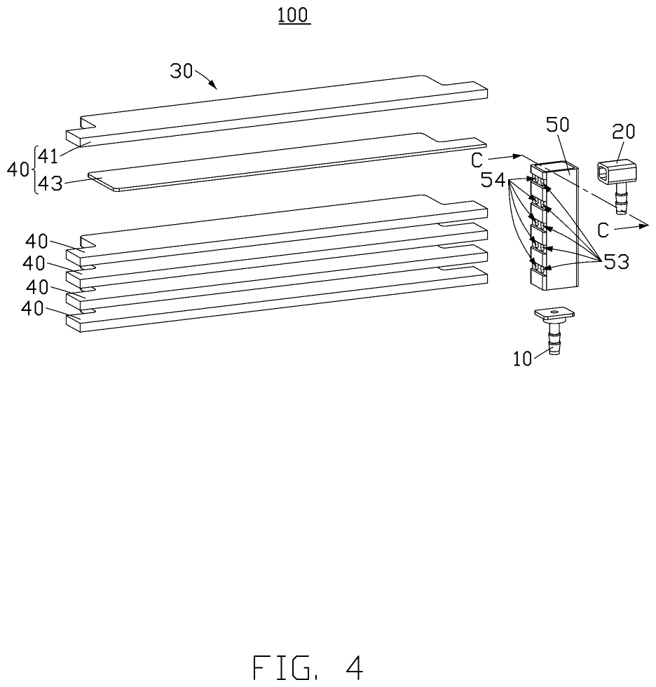

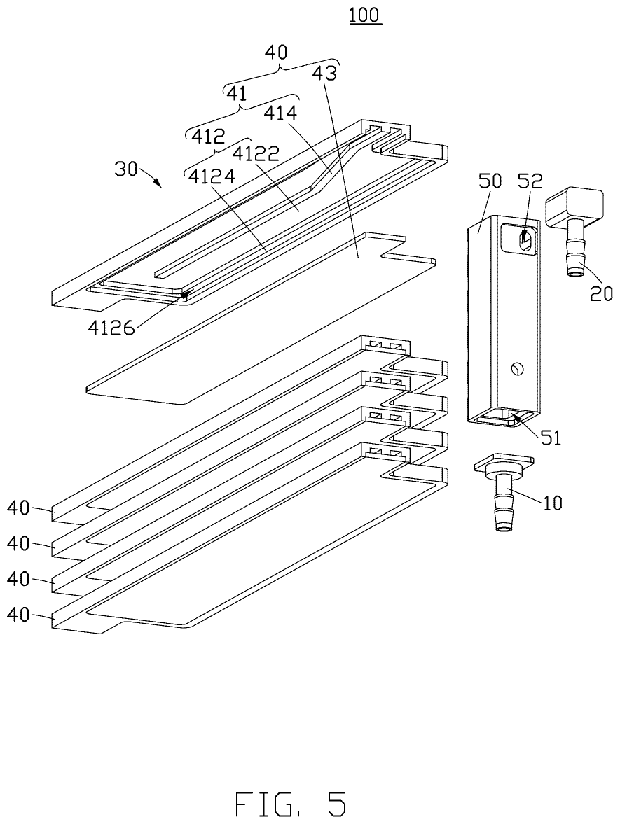

Referring to FIGS. 3, 4, and 5, each heat dissipating plate 40 includes a first cover plate 41 and a second cover plate 43. The first cover plate 41 includes a main body 412 and a strengthening rib 414. The main body 412 and the second cover plate 43 form an accommodating space 45. The strengthening rib 414 is located in the accommodating space 45. The strengthening rib 414 divides the accommodating space 45 into a first channel 452 and a second channel 454. The first channel 452 communicates with the second channel 454. The working fluid 240 can enter the heat dissipating plate 40 from the first channel 452 and expel the heat dissipating plate 40 from the second channel 454.

The main body 412 is roughly flat-shaped. The main body 412 includes a top panel 4122 and a side panel 4124. The side panel 4124 surrounds the top panel 4122. The strengthening rib 414 is located on the top panel 4122 and spaced apart from the side panel 4124. The strengthening rib 414 is in contact with the second cover plate 43. The strengthening rib 414 divides the accommodating space 45 into the first channel 452 and the second channel 454, thereby facilitating the flow of the working fluid 240 entering the heat dissipating plate 40 along a designated pathway. Furthermore, the strengthening rib 414 also serves as a support for the top panel 4122 to enhance the strength of the heat dissipating plate 40, thereby reducing the risk of deformation or collapse.

The side panel 4124 is provided with a recess 4126. The recess 4126 is formed at a side of the side panel 4124 towards the top panel 4122. An edge of the second cover plate 43 is located in the recess 4126. That is, the second cover plate 43 is embedded in the first cover plate 41, which not only reduces an overall thickness of each heat dissipating plate 40, but also enhances a sealing performance between the first cover plate 41 and the second cover plate 43, thereby preventing the working fluid 240 from leaking out of the heat dissipating plate 40.

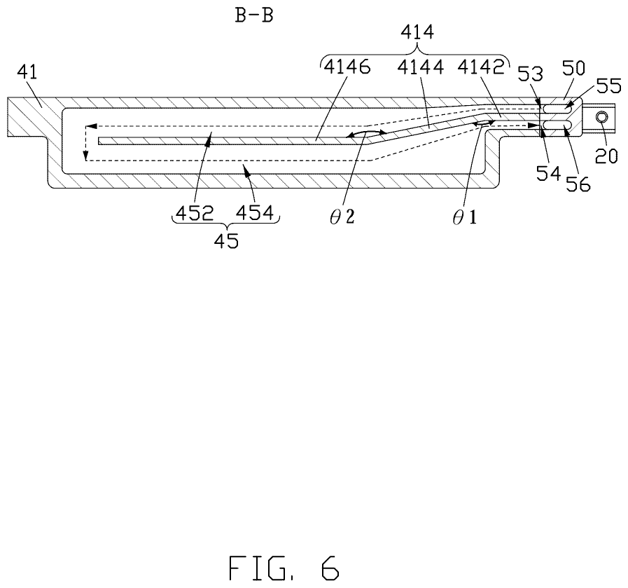

Referring to FIG. 6, each heat dissipating plate 40 includes one strengthening rib 414. The strengthening rib 414 is bent. The strengthening rib 414 can increase a flow path of the working fluid 240 to extend the heat exchange time between the working fluid 240 and the working member 230, thereby enhancing the heat dissipation performance of the radiator 100. If there are too many strengthening ribs 414, the working fluid 240 will absorb too much heat, which will reduce the heat exchange rate and be detrimental to the improvement of the heat dissipation performance of the radiator 100. At the same time, too many strengthening ribs 414 will also reduce the volume of the accommodating space 45 for the working fluid 240, which is also unfavorable for enhancing the heat dissipation performance of the radiator 100.

The strengthening rib 414 can include a first bending section 4142, a second bending section 4144, and a third bending section 4146. The first bending section 4142 is connected to the liquid separator 50, and the second bending section 4144 is connected to the first bending section 4142 and the third bending section 4146.

A first angle between the first bending section 4142 and the second bending section 4144 is an obtuse angle, and a second angle between the second bending section 4144 and the third bending section 4146 is also an obtuse angle, which facilitates smoother flow of the working fluid 240, increases the flow rate of the working fluid 240, and thereby improves the heat dissipation performance of the radiator 100.

The first bending section 4142 and the third bending section 4146 can also be parallel to each other, which can further improve the heat dissipation performance of the radiator 100.

In other embodiments, the strengthening rib 414 can also be straight. When the accommodating space 45 is relatively small, the straight strengthening rib 414 can reduce the volume occupied by the strengthening rib 414, thereby increasing the space for the first channel 452 and the second channel 454. This is beneficial for improving the flow rate of the working fluid 240 in a limited space, which in turn enhances the heat dissipation performance of the radiator 100.

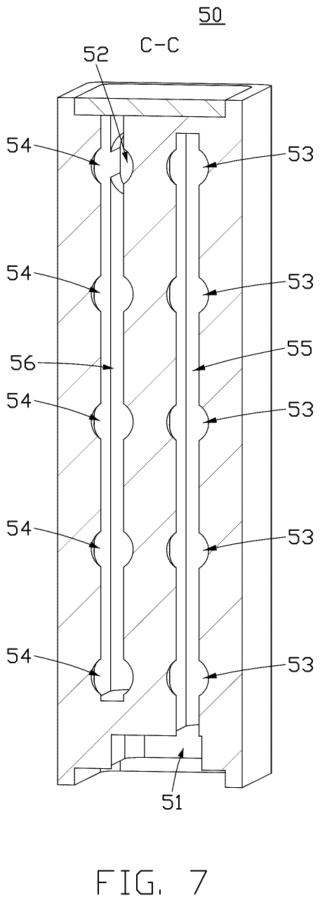

Referring to FIG. 7, the liquid separator 50 is located on the same side of the heat dissipating plates 40. The liquid separator 50 includes a liquid inlet 51, a liquid outlet 52, a plurality of outlets 53, and a plurality of inlets 54. The liquid inlet 51 communicates with the inlet connector 10. The liquid outlet 52 communicates with the outlet connector 20. The liquid inlet 51 communicates with the outlets 53. The liquid outlet 52 communicates with the inlets 54. The outlets 53 communicate with the first channel 452. The inlets 54 communicates with the second channel 454. With the liquid separator 50 located on the same side of the heat dissipating plates 40, the working fluid 240 enters and expels from the same side of the heat dissipating plates 40, which extends the flow path of the working fluid 240 in the heat dissipating plates 40, extends the heat exchange time between the working fluid 240 and the working member 230, and improves the heat dissipation performance of the radiator 100. Moreover, compared to embodiments without the strengthening rib 414, the flow rate of the working fluid 240 in the first channel 452 and the second channel 454 is increased, thereby enhancing the heat dissipation performance of the radiator 100. Furthermore, the liquid separator 50 is located on the same side of the heat dissipating plates 40, which can reduce the risk of manufacturing difficulty, welding complexity, and dimensional defects of the radiator 100.

The liquid separator 50 further includes a first accommodating groove 55 and a second accommodating groove 56. The accommodating groove 55 and the second accommodating groove 56 are spaced apart from each other. The outlets 53 communicate with the first accommodating groove 55. The inlets 54 communicate with the second accommodating groove 56. The working fluid 240 entering the heat dissipating plates 40 from the liquid separator 50 and the working fluid 240 expelling the heat dissipating plates 40 to the liquid separator 50 flow through separate channels. The working fluid 240 entering the heat dissipating plates 40 from the liquid separator 50 undergoes heat exchange in the heat dissipating plates 40 before exiting to the liquid separator 50. This is beneficial for improving the heat dissipation performance of the radiator 100 and prevents the mixing of working fluid 240 that has undergone heat exchange with working fluid 240 that has not, which can reduce the heat dissipation performance of the radiator 100.

When the inlet tube 210 and the outlet tube 220 are installed on the radiator 100, the installation positions of the inlet tube 210 and the outlet tube 220 can be swapped, which will correspondingly change the flow direction of the working fluid 240. The heat dissipation principle remains unchanged.

The radiator 100 further includes a plurality of thermal conductive layers 60 (referring to FIG. 1). The thermal conductive layers 60 are located on the surfaces of the first cover plate 41 facing away from the second cover plate 43; and/or the thermal conductive layers 60 are located on the surfaces of the second cover plate 43 facing away from the first cover plate 41. The thermal conductive layers 60 are connected to the working member 230 and the heat dissipating plates 40. The thermal conductive layers 60 may include, but is not limited to, being adhered or coated on the surface of the heat dissipating plates 40. The thermal conductive layers 60 can increase the heat transfer rate between the working member 230 and the heat dissipating plates 40, thereby improving the heat dissipation performance of the radiator 100.

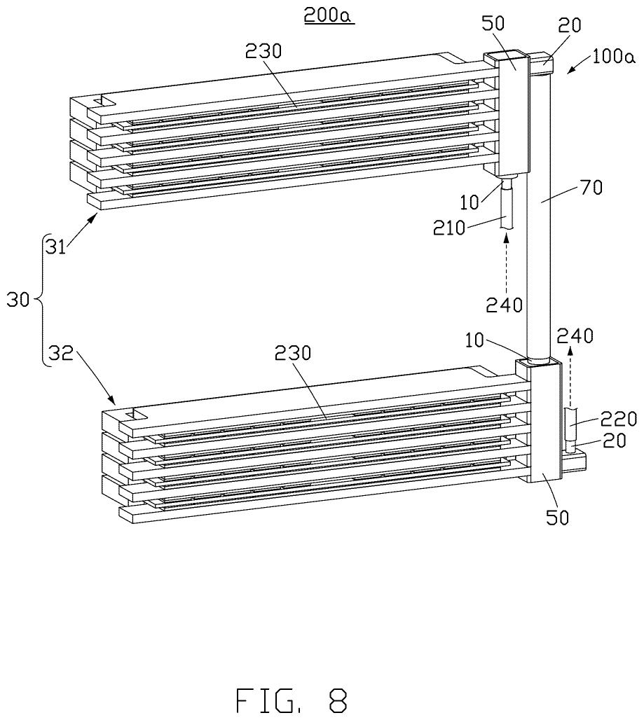

Referring to FIG. 8, a terminal device 200a is provided according to another embodiment of the present disclosure. The terminal device 200a includes a radiator 100a. The radiator 100a includes a plurality of heat dissipating assemblies 30 and can simultaneously dissipate heat for a plurality of working members 230.

The heat sink 100a can further include at least one connecting tube 70. The connecting tube 70 can connect two heat dissipating assemblies 30. The number of connecting tube 70 can be one or more, and the number of connecting tube 70 is related to the number of heat dissipating assemblies 30 and the way in which the connecting tube 70 connect the heat dissipating assemblies 30. When there are a plurality of connecting tubes 70, they can be connected to heat dissipating assemblies 30 in series, parallel, or other configurations.

The connecting tube 70 can communicate the outlet connector 20 of one heat dissipating assembly 30 with the inlet connector 10 of another heat dissipating assembly 30. Specifically, taking an example where the radiator 100a includes two heat dissipating assemblies 30, the two heat dissipating assemblies 30 are defined as a first heat dissipating assembly 31 and a second heat dissipating assembly 32. The connecting tube 70 communicates with the outlet connector 20 of the first heat dissipating assembly 31 and the inlet connector 10 of the second heat dissipating assembly 32. The inlet tube 210 communicates with the liquid inlet 51 of the first heat dissipating assembly 31, and the liquid outlet 52 of the second heat dissipating assembly 32 communicates with the outlet connector 20. The working fluid 240 entering from the inlet tube 210 flows through the inlet connector 10 connected to the liquid inlet 51 of the first heat dissipating assembly 31, the accommodating space 45 of the first heat dissipating assembly 31, the outlet connector 20 connected to the liquid outlet 52 of the first heat dissipating assembly 31, the connecting tube 70, the inlet connector 10 connected to the liquid inlet 51 of the second heat dissipating assembly 32, the accommodating space 45 of the second heat dissipating assembly 32, and the outlet connector 20 connected to the liquid outlet 52 of the second heat dissipating assembly 32, and then expels from the outlet tube 220.

The liquid separator 50 of the radiator 100 (or 100a) located on the same side of the heat dissipating plates 40, allowing the working fluid 240 to enter and expels from the same side of the heat dissipating plates 40, which extends the flow path of the working fluid 240 in the heat dissipating plates 40, extends the heat exchange time between the working fluid 240 and the working member 230, and enhances the heat dissipation performance of the radiator 100 (or 100a). Moreover, compared to embodiments without the strengthening rib 414, the flow rate of the working fluid 240 in the first channel 452 and the second channel 454 is increased, enhancing the heat dissipation performance of the radiator 100 (or 100a). Furthermore, positioning the liquid separator 50 on the same side of the heat dissipating plates 40 can reduce the manufacturing difficulty, welding complexity, and the risk of dimensional defects of the radiator 100 (or 100a).

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A radiator comprising:
an inlet connector;
an outlet connector; and
at least one heat dissipating assembly, each of the at least one heat dissipating assembly comprising:
a plurality of heat dissipating plates, each of the plurality of heat dissipating plates comprising a first cover plate and a second cover plate, the first cover plate comprising a main body and a strengthening rib, the main body and the second cover plate forming an accommodating space, the strengthening rib located in the accommodating space and dividing the accommodating space into a first channel and a second channel communicating with the first channel; and
a liquid separator located on a side of the plurality of heat dissipating plates, the liquid separator comprising a liquid inlet, a liquid outlet, a plurality of outlets, and a plurality of inlets;
wherein the liquid inlet communicates with the inlet connector, the liquid outlet communicates with the outlet connector, the liquid inlet communicates with the plurality of outlets, the liquid outlet communicates with the plurality of inlets, the plurality of outlets communicates with the first channel, and the plurality of inlets communicates with the second channel.

2. The radiator of claim 1, wherein the main body comprises a top panel and a side panel, the side panel surrounds the top panel, the strengthening rib is located on the top panel and spaced apart from the side panel, and the strengthening rib is in contact with the second cover plate.

3. The radiator of claim 2, wherein the side panel is provided with a recess, the recess is formed at a side of the side panel towards the top panel, and an edge of the second cover plate is located in the recess.

4. The radiator of claim 1, wherein each of the plurality of heat dissipating plates comprises the strengthening rib, and the strengthening rib is bent.

5. The radiator of claim 4, wherein the strengthening rib comprises a first bending section, a second bending section, and a third bending section, the first bending section is connected to the liquid separator, and the second bending section is connected to the first bending section and the third bending section.

6. The radiator of claim 5, wherein a first angle between the first bending section and the second bending section is an obtuse angle, and a second angle between the second bending section and the third bending section is an obtuse angle.

7. The radiator of claim 1, wherein the liquid separator further comprises a first accommodating groove and a second accommodating groove, the first accommodating groove and the second accommodating groove are spaced apart from each other; the plurality of outlets communicates with the first accommodating groove, and the plurality of inlets communicates with the second accommodating groove.

8. The radiator of claim 1, further comprising a plurality of thermal conductive layers, wherein the plurality of thermal conductive layers is located on a surface of the first cover plate facing away from the second cover plate; and/or the plurality of thermal conductive layers are located on a surface of the second cover plate facing away from the first cover plate.

9. The radiator of claim 1, wherein the radiator comprises a plurality of heat dissipating assemblies, the radiator further comprises at least one connecting tube, the at least one connecting tube is configured to communicate the outlet connector of one of the plurality of heat dissipating assemblies with the inlet connector of another one of the plurality of heat dissipating assemblies.

10. A terminal device comprising:
a radiator comprising:
an inlet connector;
an outlet connector; and
at least one heat dissipating assembly, each of the at least one heat dissipating assembly comprising:
a plurality of heat dissipating plates, each of the plurality of heat dissipating plates comprising a first cover plate and a second cover plate, the first cover plate comprising a main body and a strengthening rib, the main body and the second cover plate forming an accommodating space, the strengthening rib located in the accommodating space and dividing the accommodating space into a first channel and a second channel communicating with the first channel; and
a liquid separator located on a side of the plurality of heat dissipating plates, the liquid separator comprising a liquid inlet, a liquid outlet, a plurality of outlets, and a plurality of inlets;
an inlet tube communicating with the inlet connector;
an outlet tube communicating with the outlet connector; and
a working member located between each two adjacent of the plurality of heat dissipating plates;
wherein the inlet tube is configured to receive a working fluid, the radiator is configured to heat exchange the working fluid, the outlet tube is configured to expel the working fluid; the liquid inlet communicates with the inlet connector, the liquid outlet communicates with the outlet connector, the liquid inlet communicates with the plurality of outlets, the liquid outlet communicates with the plurality of inlets, the plurality of outlets communicates with the first channel, and the plurality of inlets communicates with the second channel.

11. The terminal device of claim 10, wherein the main body comprises a top panel and a side panel, the side panel surrounds the top panel, the strengthening rib is located on the top panel and spaced apart from the side panel, and the strengthening rib is in contact with the second cover plate.

12. The terminal device of claim 11, wherein the side panel is provided with a recess, the recess is formed at a side of the side panel towards the top panel, and an edge of the second cover plate is located in the recess.

13. The terminal device of claim 10, wherein each of the plurality of heat dissipating plates comprises the strengthening rib, and the strengthening rib is bent.

14. The terminal device of claim 13, wherein the strengthening rib comprises a first bending section, a second bending section, and a third bending section, the first bending section is connected to the liquid separator, and the second bending section is connected to the first bending section and the third bending section.

15. The terminal device of claim 14, wherein a first angle between the first bending section and the second bending section is an obtuse angle, and a second angle between the second bending section and the third bending section is an obtuse angle.

16. The terminal device of claim 10, wherein the liquid separator further comprises a first accommodating groove and a second accommodating groove, the first accommodating groove and the second accommodating groove are spaced apart from each other; the plurality of outlets communicates with the first accommodating groove, and the plurality of inlets communicates with the second accommodating groove.

17. The terminal device of claim 10, wherein the radiator further comprises a plurality of thermal conductive layers, the plurality of thermal conductive layers is located on a surface of the first cover plate facing away from the second cover plate; and/or the plurality of thermal conductive layers are located on a surface of the second cover plate facing away from the first cover plate.

18. The terminal device of claim 10, wherein the radiator comprises a plurality of heat dissipating assemblies, the radiator further comprises at least one connecting tube, and the at least one connecting tube is configured to communicate the outlet connector of one of the plurality of heat dissipating assemblies with the inlet connector of another one of the plurality of heat dissipating assemblies.
